(19) United States
(12) Patent Application Publication
(10) Pub. No.: US 2009/0053878 A1
(43) Pub. Date: Feb. 26, 2009

(54) METHOD FOR FABRICATION OF SEMICONDUCTOR THIN FILMS USING FLASH LAMP PROCESSING

(76) Inventors: Maxim Kelman, Mountain View, CA (US); Francesco Lemmi, Sunnyvale, CA (US)

Correspondence Address: Foley & Lardner LLP, 150 East Gilman Street, Madison, WI, 53701-1497, US

(21) Appl. No.: 11/875,261

(22) Filed: Oct. 19, 2007

Related U.S. Application Data
(63) Continuation-in-part of application No. 11/842,466, filed on Aug. 21, 2007.

(51) Int. Cl. H01L 21/20

(52) U.S. Cl. 438/509; 257/E21.09

(57) ABSTRACT

A method for creating a Group IV semiconductor densified thin film is disclosed. The method includes applying a colloidal dispersion to a substrate, wherein the colloidal dispersion includes a plurality of Group IV semiconductor nanoparticles and an organic solvent. The method also includes removing the organic solvent by applying a first temperature for a first time period to form a Group IV semiconductor non-densified thin film; and heating the Group IV semiconductor non-densified thin film to a second temperature for a second time period, wherein the second temperature is a pre-heating target temperature. The method further includes heating the Group IV semiconductor non-densified thin film to a third temperature for a third time period with a flash lamp apparatus, wherein the third temperature is equal to or greater than a sintering temperature, wherein a Group IV semiconductor densified thin film is created.

### CROSS-REFERENCE TO RELATED APPLICATIONS

This application claims the benefit of U.S. patent application Ser. No. 11/842,466 filed Aug. 21, 2007, the entire disclosure of which is incorporated by reference.

### FIELD OF DISCLOSURE

This disclosure relates in general to semiconductor thin films made from semiconductor nanoparticles, and in particular to methods for making the thin films.

### BACKGROUND

Semiconductors form the basis of modern electronics. Possessing physical properties that can be selectively modified and controlled between conduction and insulation, semiconductors are essential in most modern electrical devices (e.g., computers, cellular phones, photovoltaic cells, etc.). Group IV semiconductors generally refer to those elements in the fourth column of the periodic table (e.g., carbon, silicon, germanium, etc.).

The Group IV semiconductor materials enjoy wide acceptance as the materials of choice in a range devices in numerous markets such as communications, computation, and energy. Currently, particular interest within the art is aimed at improving semiconductor thin film technologies to overcome widely recognized disadvantages of semiconductor thin film made with chemical vapor deposition (CVD) technologies.

With the emergence of nanotechnology, there is growing interest in using semiconductor nanoparticles, and particularly Group IV semiconductor nanoparticles, as a building material for a wide variety of modern electronic devices. One advantage of Group IV semiconductor nanoparticle materials is the potential for flexible, high volume, low-cost deposition processes, such as printing, for the ready deposition of a variety of Group IV nanoparticles on a range of substrate materials.

A number of techniques, including resistive and radiative heating, have proven to be useful in the preparation of conventional Group IV semiconductor wafer-based devices. These techniques are generally aimed at annealing, dopant activation and/or recrystallization of bulk semiconductor materials, such as silicon wafers. More recently, laser processing has been proposed for use in fusing Group IV nanoparticles into a continuous layer in the fabrication of a transistor. (See U.S. patent application Ser. No. 10/533,291, entitled Electronic Components).

Although conventional processing techniques have demonstrated value in the semiconducting processing industry, a need remains for a more efficient, lower cost alternative for processing semiconductor wafer based devices.

### SUMMARY

The invention relates, in one embodiment, to a method for creating a Group IV semiconductor densified thin film. The method includes applying a colloidal dispersion to a substrate, wherein the colloidal dispersion includes a plurality of Group IV semiconductor nanoparticles and an organic solvent. The method also includes removing the organic solvent by applying a first temperature for a first time period to form a Group IV semiconductor non-densified thin film; and heating the Group IV semiconductor non-densified thin film to a second temperature for a second time period, wherein the second temperature is a pre-heating target temperature. The method further includes heating the Group IV semiconductor non-densified thin film to a third temperature for a third time period with a flash lamp apparatus, wherein the third temperature is equal to or greater than a sintering temperature, wherein a Group IV semiconductor densified thin film is created.

The invention relates, in another embodiment, to a method for creating a set of Group IV semiconductor densified thin films. The method includes applying a first colloidal dispersion to a substrate, wherein the first colloidal dispersion includes a first plurality of Group IV semiconductor nanoparticles and a first organic solvent; and applying a second colloidal dispersion to the first colloidal dispersion, wherein the second colloidal dispersion includes a second plurality of Group IV semiconductor nanoparticles and a second organic solvent. The method also includes removing the first organic solvent and the second organic solvent by applying a first temperature for a first time period to form a first Group IV semiconductor non-densified thin film and a second Group IV semiconductor non-densified thin film. The method further includes heating the first Group IV semiconductor non-densified thin film and the second Group IV semiconductor non-densified thin film to a second temperature for a second time period, wherein the second temperature is a pre-heat temperature. The method also includes heating the first Group IV semiconductor non-densified thin film and the second Group IV semiconductor non-densified thin film to a third temperature for a third time period with a flash lamp apparatus, wherein the third temperature is equal to or greater than a sintering temperature; wherein a third Group IV semiconductor densified thin film and a fourth Group IV semiconductor densified thin film are created.

### BRIEF DESCRIPTION OF THE DRAWINGS

The present invention is illustrated by way of example, and not by way of limitation, in the figures of the accompanying drawings, in which like reference numerals refer to similar elements and in which:

FIG. 1 is a schematic diagram of a thermal processing profile for a method of converting a thin layer of semiconductor nanoparticles into a dense semiconductor thin film, in accordance with the invention;

FIGS. 2A-2F show a process for fabricating a p-i-n junction from Group IV semiconductor nanoparticles using flash lamp processing, in accordance with the invention;

FIGS. 3A-B show an alternative process for fabricating a p-i-n junction from Group IV semiconductor nanoparticles using flash lamp processing, in accordance with the invention;

FIGS. 4A-B show an alternative process for fabricating a dense semiconductor thin film on native Group IV semiconductor substrate using flash lamp processing, in accordance with the invention;

FIGS. 5A-B show scanning electron micrographs of a single Si nanoparticle film before and after flash-lamp processing, in accordance with the invention;

FIG. 6 shows scanning electron micrograph of a Si nanoparticle film deposited on a dense Si layer and processed with a flash lamp, in accordance with the invention;

FIG. 7 shows a simplified SIMS analysis of an intrinsic Si nanoparticle film deposited on an arsenic doped poly-silicon layer and processed with a flash lamp, in accordance with the invention; and

FIG. 8 shows a comparison of a halogen lamp emission and a flash lamp emission to the absorption spectrum for a typical Si nanoparticle film, in accordance with the invention.

### DETAILED DESCRIPTION

The present invention will now be described in detail with reference to a few preferred embodiments thereof, as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

The present invention relates to semiconductor thin films made from nanoparticles and more specifically to semiconductor thin films made from Group IV semiconductor nanoparticles using flash lamp processing. Generally, a thin film may be made by sintering a layer of semiconductor nanoparticles into a densified thin film having dense connected regions. Sintering is generally a method for making the nanoparticles adhere to each other to induce the densification of the material and the formation of a densified thin film. Typically, sintering temperature refers to a minimum temperature below the bulk melting temperature of the material where there is significant mass transport to enable the densification and strengthening of the particulate body. For most bulk powder materials, sintering takes place at reasonable rates for temperatures greater than T>Tₘ/2 or T>Tₘ/3, where Tₘ is the melting temperature of the material. An informative discussion of melting and sintering nanoparticles may be found in A. N. Goldstein, The melting of silicon nanocrystals: Submicron thin-film structures derived from nanocrystal precursors, APPLIED PHYSICS, 1996. Sintering may occur to such an extent that individual nanoparticles within a film are no longer discernable.

In the current invention, sintering is conducted by exposing a layer of nanoparticles to intense electromagnetic radiation emitted from a flash lamp for a time sufficient to convert the nanoparticles into a dense thin film in which the nanoparticles adhere to each other. In an advantageous manner, the use of a flash lamp in the sintering process allows broad spectrum electromagnetic radiation to uniformly heat a large area with control over the depth profile of the substrate. Subsequently, potential problems associated with laser processing, such as stitching caused by the need to raster a laser over a large substrate surface area and substrate ablation, may be avoided.

Additionally, the broad spectrum radiation provided by a flash lamp may cover a range of wavelengths at which the semiconductor nanoparticles absorb, thereby requiring only a single radiation pulse to provide efficient nanoparticle heating. Furthermore, the ability to control the energy density and duration of the flash in a flash lamp processing scheme allows the user to selectively thermally process individual layers of semiconductor in a multilayer structure, without heating adjacent, underlying layers. Such selective heating may make it possible to minimize or eliminate unwanted dopant atom diffusion between layers and/or to utilize substrate materials having low melting temperatures. Flash lamp processing of nanoparticle-based films also may enable the formation of abrupt dopant concentration profiles, as the dopant atoms do not have time to diffuse during the short temperature excursion.

In general, a nanoparticle is a microscopic particle with at least one dimension less than 100 nm. The term “Group IV nanoparticle” generally refers to hydrogen terminated Group IV nanoparticles having an average diameter between about 1 nm to 100 nm, and composed of silicon, germanium, carbon, or combinations thereof. The term “Group IV nanoparticle” includes Group IV nanoparticles that are doped.

In comparison to a bulk material (>100 nm) which tends to have constant physical properties regardless of its size (e.g., melting temperature, boiling temperature, density, conductivity, etc.), nanoparticles may have physical properties that are size dependent, and hence useful for applications such as junctions.

The semiconductor nanoparticles from which the densified semiconductor thin films are made may be composed of a variety of semiconductor elements and alloys thereof. The nanoparticles may be single-crystalline, polycrystalline, amorphous or a combination thereof. The nanoparticles may be doped, undoped, or a combination thereof. The nanoparticles may be coated with organic capping agents or may have a core-shell structure, wherein the nanoparticle cores and shells have different chemical compositions. Methods for making such nanoparticles are known.

One illustrative example of such methods is the radiofrequency plasma production of semiconductor nanoparticles is described in U.S. patent application Ser. No. 11/775,509, entitled Concentric Flow-Through Plasma Reactor and Methods Therefor, the entire disclosure of which is incorporated by reference.

In general, these plasma-based methods are carried out as follows: a semiconductor precursor gas (e.g., a gas of a Group IV-containing molecule, such as silane), one or more of inert gases and, optionally, a dopant gas (i.e., a gas of a dopant element-containing molecule) are flowed into a plasma reaction zone between a set of electrodes. An RF (radiofrequency) signal is then applied to the powered electrode in order to strike a plasma which subsequently dissociates the semiconductor precursor gas molecules to form semiconductor nanoparticles which may be collected downstream of the reaction zone. As discussed in the above-mentioned references, the precursor gases, dopant gases, plasma conditions and electrode geometries may vary, depending on the desired nature, size and properties of the semiconductor nanoparticles.

In an initial step in the production of a densified semiconductor thin film, the nanoparticles are deposited as one or more layers onto an underlying substrate. Because of their small size, nanoparticles tend to be difficult to manipulate. Consequently, in an advantageous manner, assembled nanoparticles may be suspended in a colloidal dispersion or colloid, such as an ink, in order to deposit the nanoparticles. Nanoparticle layer formation is advantageously accomplished by applying the nanoparticles to the substrate in the form of a colloidal dispersion. Examples of application methods for the inks include, but are not limited to, roll coating, slot die coating, gravure printing, flexographic drum printing, and ink jet printing methods.

In general, the nanoparticles are transferred into the colloidal dispersion under a vacuum, or else an inert substantially oxygen-free environment. In addition, the use of particle dispersal methods and equipment such as sonication, high shear mixers, and high pressure/high shear homogenizers may be used to facilitate dispersion of the nanoparticles in a selected solvent or mixture of solvents.

Examples of solvents include alcohols, aldehydes, ketones, carboxylic acids, esters, amines, organosiloxanes, halogenated hydrocarbons, sulfides, and other hydrocarbon solvents. In addition, the solvents may be mixed in order to optimize physical characteristics such as viscosity, density, polarity, etc.

In addition, in order to better disperse the nanoparticles in the colloidal dispersion, nanoparticle capping groups may be formed with the addition of organic compounds, such as alcohols, aldehydes, ketones, carboxylic acids, esters, and amines, as well as organosiloxanes. Alternatively, capping groups may be added in-situ by the addition of gases into the plasma chamber. These capping groups may be subsequently removed during the sintering process, or in a lower temperature pre-heat just before the sintering process, as described in more detail below.

For example, bulky capping agents suitable for use in the preparation of capped Group IV semiconductor nanoparticles include C4-C8 branched alcohols, cyclic alcohols, aldehydes, and ketones, such as tertiary-butanol, isobutanol, cyclohexanol, methyl-cyclohexanol, butanal, isobutanal, cyclohexanone, and oraganosiloxanes, such as methoxy(tris(trimethylsilyl)silane) (MTTMSS), tris(trimethylsilyl)silane (TTMSS), decamethyltetrasiloxane (DMTS), trimethylmethoxysilane (TMOS), terminal alkanes, etc.

Various configurations of nanoparticle colloidal dispersions can be formulated by the selective blending of doped, undoped, and/or differently doped nanoparticles. For example, various formulations of blended Group IV nanoparticle colloidal dispersions can be prepared in which the dopant level for a specific layer of a junction is formulated by blending doped and undoped Group IV nanoparticles to achieve the requirements for that layer.

Once formulated, the colloidal dispersion may be applied to a substrate and the resulting nanoparticle layer subjected to flash lamp processing in order to sinter the nanoparticles into a densified conductive film. Subsequently, the nanoparticle layer may be exposed to one or more pulses of electromagnetic radiation from a flash lamp apparatus. The flash lamp apparatus generally includes an intense radiation source, such as a Xe lamp, that emits a short burst of radiation having selected wavelengths. Typically, the radiation will cover a broad spectrum of radiation including wavelengths that are readily absorbed by the semiconductor nanoparticles.

The size and composition of the nanoparticles will generally affect absorption spectrum. As size of the particles decreases, the absorption spectrum shifts to shorter wavelength. The energy density and duration of the radiation pulse should be sufficient to convert the nanoparticles in the radiated layer into dense, sintered, semiconductor thin film. For example, silicon nanoparticles approximately 8 nm is diameter start absorbing radiation with a wavelength shorter than approximately ˜750 nm.

Suitable flash lamp apparatuses for use in the present methods are commercially available. For example, the Flash Lamp Tool FLA-100 available from FHR Anlegenbau GMBH (Ottendorf-Okrilla, Germany) may emit a broad spectrum radiation with wavelengths from about 400 nm to about 750 nm. Typically such apparatuses include: (1) a substrate pre-heating unit that includes a plurality of heat sources, such as halogen lamps, disposed beneath a substrate mounting surface; and (2) a flash lamp unit with a plurality of flash lamps disposed over and facing the substrate mounting surface. A reflector is desirably disposed over the plurality of flash lamps to direct and concentrate the radiation from the lamps onto the substrate.

During the flash lamp process, the temperature increase experienced by the surface of the sample depends on the flash lamp power, pulse duration and heat transfer within the sample. The temperature rise experienced during the flash generally correlates with flash lamp power. As the flash energy increases the temperature rise increases. Flash duration has the opposite effect. As the flash duration increases, the peak surface temperature tends to decreases as more heat is conducted away from the surface into the bulk of the sample. For the same reason, as the thermal conductivity of the substrate increases, the temperature increase experience by the sample surface decreases.

Preheating of the substrate may be necessary to compensate for the power limitations of the flash-lamp apparatus. By preheating the substrate prior to the activation of the flash lamps, the peak temperature of the sample surface can be increased.

In general, the pre-heating step may be carried out using one or more heating elements, such as heat lamps (e.g., the pre-heating step may be carried out using one or more heating elements, such as heat lamps (e.g., halogen lamps), or other heating sources. The target temperature and duration of the pre-heating step may vary depending on the size, density and nature of the nanoparticles in the deposited nanoparticle layer and the dimensions of the layer. Illustrative examples of appropriate pre-heating steps are provided in the examples that follow.

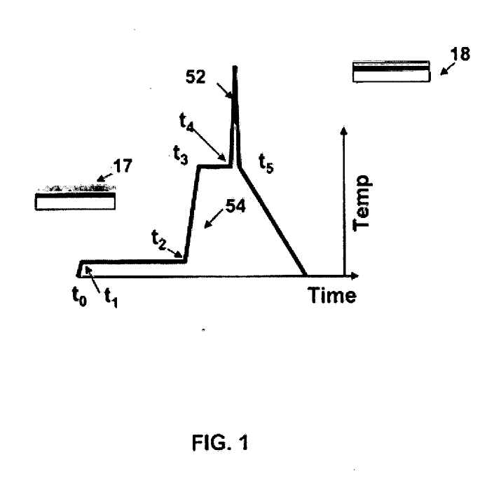

Referring now to FIG. 1, a schematic diagram is shown of a thermal processing profile for a method of converting a thin layer of semiconductor nanoparticles into a dense semiconductor thin film, in accordance with the invention. The processing profile shows the timeline for the various heating steps, as well as the resulting temperatures experienced by the nanoparticles during flash lamp processing 52. In this process a layer of semiconductor nanoparticles 17 supported on an underlying substrate is converted into a dense semiconductor thin film 18.

In general, the nanoparticles undergo a low-temperature solvent removal step with an initial temperature ramp-up time from t₀ to t₁, followed by a temperature hold time from t₁ to t₂. The solvent removal step does not necessarily have to be done in the same chamber as the flash process. At t₂, the nanoparticles are heated to an intermediate temperature t₃ and held at a constant temperature until time t₄. At time t₄ the particles are exposed to an intense flash of radiation from the flash lamp radiation source which results in a large, rapid increase in the temperature of the nanoparticle layer.

After the flash, at time t₅ the particles are cooled down to room temperature. Suitable processing parameters, including pre-heating ramp-up times, temperatures and duration, and flash energy densities and durations for the formation of dense silicon films from silicon nanoparticles are provided in the examples below. For purposes of illustration only, typical processing parameters for the formation of Group IV thin films from Group IV semiconductor nanoparticles may be (but are not necessarily) as follows:

a solvent removal temperature of about 100° C. to about 450° C., and an interval of about 5 minutes to about 30 minutes;

a pre-heating target temperature from about 100° C. to about 800° C.;

a pre-heating ramp-up time from about 0 minutes to about 1 minute;

a pre-heating hold time from about 0.5 minutes to about 5 minutes;

a flash energy density of about 3 J/cm² to about 120 J/cm²; and

a flash duration of about 0.8 msec to about 3 msec.

In general, shorter flash durations are beneficial as they allow the temperature of the substrate to stay low.

The present methods may be used to produce single layer structures composed of a single semiconductor thin film, or multilayered structures composed of multiple semiconductor thin film layers, wherein the semiconductor materials in the different layers of the multilayered structures are composed of semiconductors having different compositions, different doping characteristics, different degrees of crystallinities, or combinations of these features.

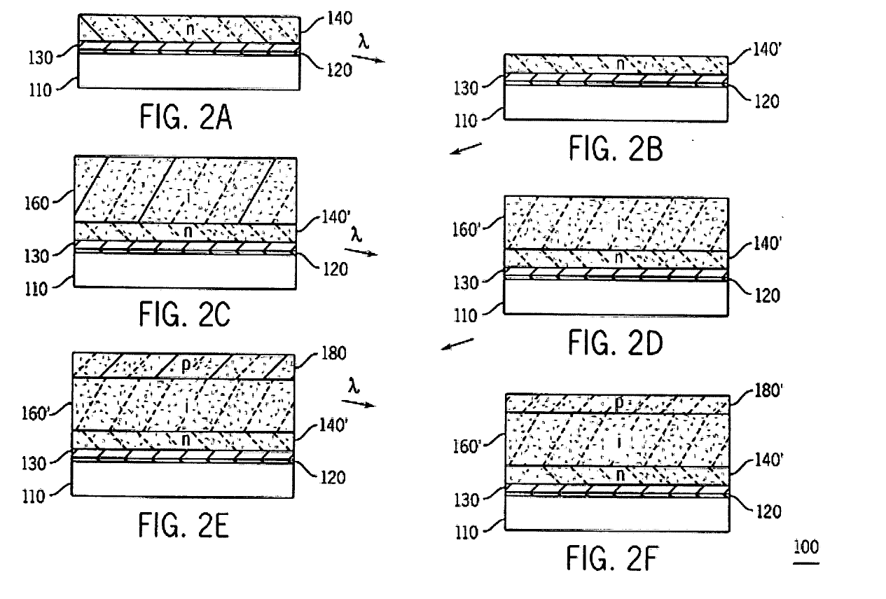

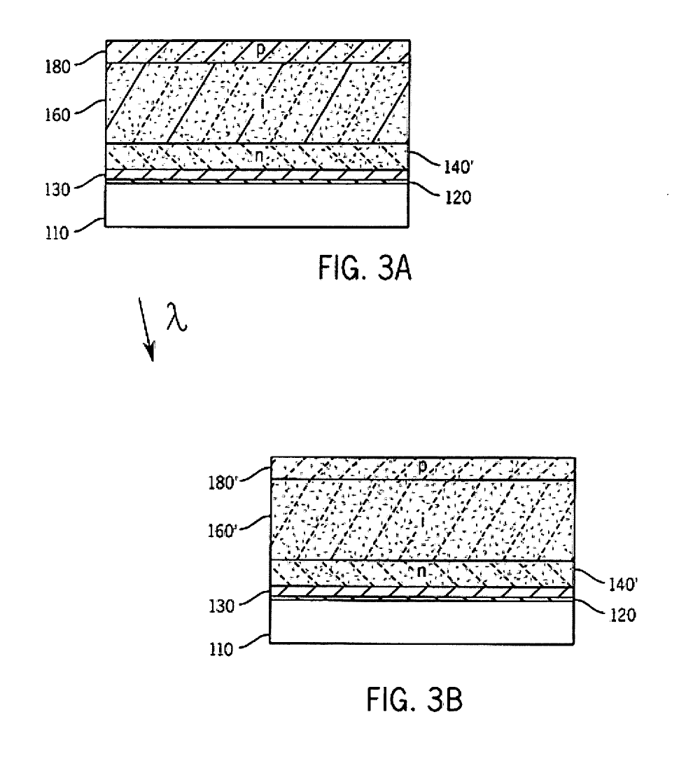

Referring now to FIGS. 2A-F, a set of schematic representations are shown of a flash lamp processing scheme used to fabricate a p-i-n junction using sequential deposition and sintering steps, in accordance with the invention. Such multilayered structures may be processed using sequential nanoparticle deposition and flash lamp processing steps, as illustrated in FIGS. 2A-F, or using a series of nanoparticle deposition steps, followed by flash lamp processing, as illustrated in FIGS. 3A-B.

FIG. 2A shows a thin layer of n-doped semiconductor nanoparticles 140 deposited over a underlying substrate 110. In this illustrative structure, a layer of insulating material 120 and an electrode 130 are disposed between the substrate 110 and the layer of nanoparticles 140.

Substrate 110 may be made from a variety of materials, including semiconductor materials, insulating materials, metals and flexible polymeric materials. Because the flash lamp apparatus is able to irradiate a large area in a single shot, the surface area of the substrate may be quite large. For example, the substrate may have a diameter on the order of ten centimeters, or greater, and still undergo single shot flash lamp processing. Common substrate materials may be selected from, for example, silicon dioxide-based substrates, such as, quartz and glasses, such as soda lime and borosilicate glasses. Flexible stainless steel sheets are an example of a suitable metal substrate. Polymers, such as polyimides and aromatic fluorene-containing polyarylates are examples of suitable polymeric substrates. Native semiconductor substrates are another class of substrate commonly used in the preparation of a range of modern electronic devices.

The first electrode 130 is made from and electrically conductive material, such as a metal. Suitable metals include, but are not limited to, aluminum, molybdenum, silver, chromium, titanium, nickel, and platinum. For a typical optoelectronic device, such as a photovoltaic cell, the first electrode 130 may have a thickness of about 10 nm to about 1000 nm. However, electrodes having a thickness outside this range are also suitable.

The optional insulating layer 120 is a layer of dielectric material that may protect the subsequently-fabricated semiconductor thin films from contaminants and/or dopants that may diffuse from the substrate into the semiconductor thin film during processing. In addition, the insulating layer 120 may prevent shorting within the device and/or planarize an uneven surface of the underlying substrate 110. The insulating layer 120 made be made from any suitable dielectric material such as, but not limited to, silicon nitride, alumina, and silicon oxides. For a typical optoelectronic device, such as a photovoltaic cell, the insulating layer 120 may have a thickness of about 50 nm to about 100 nm. However, dielectric layers having a thickness outside this range are also suitable.

As previously mentioned, the layer of n-doped semiconductor nanoparticles 140 is desirably applied to the substrate structure in the form of a colloid, such as an ink. As applied, this layer may have a thickness of about 50 nm to about 400 nm, although nanoparticles layers having a thickness outside this range may also be used. After the nanoparticle layer 140 is deposited, it is exposed to flash lamp processing, as illustrated, for example, in FIGS. 2A-F to form a dense, semiconductor thin film 140′. As a result of sintering and densification, the thickness of this layer is typically reduced. For example, the densified semiconductor thin film may have a thickness of about 25 nm to about 200 nm, although thin films having thicknesses outside this range may also be produced.

After the fabrication of the n-type thin film 140′ of FIG. 2B, a layer of intrinsic semiconductor nanoparticles is deposited (e.g., printed) on n-type thin film 140′ to form a layer of intrinsic semiconductor nanoparticles 160, as shown in FIG. 2C. If the p-i-n junction is to be used in an optoelectronic device, such as a photovoltaic cell, this layer of intrinsic nanoparticles typically has a thickness of about 400 nm to about 6 micron.

However, intrinsic layers having thicknesses outside this range may also be employed. After undergoing flash lamp processing as illustrated, for example, in FIG. 1, a densified intrinsic semiconductor thin film 160′ is formed, as illustrated in FIG. 2D. Again, due to sintering and densification, the thin film typically has a reduced thickness. For example, flash lamp processes may produce an intrinsic thin film having a thickness of about 200 nm to about 3 microns. However, thin films having thicknesses outside of this range may also be formed.

By using the sequential deposition and flash lamp processing steps shown here, the proper selection of radiation wavelengths, energy density and flash duration allows for the careful control the thermal depth profile within the structure, thereby making it possible to heat the layer of intrinsic semiconductor nanoparticles without heating the previously-formed n-type semiconductor thin film. This is advantageous because it minimizes or eliminates unwanted dopant diffusion from the n-type semiconductor thin film into the intrinsic semiconductor thin film.

After the fabrication of intrinsic thin film 160′ of FIG. 2D, a layer of p-doped semiconductor nanoparticles 180 may be deposited over the intrinsic semiconductor thin film, as shown in FIG. 2E. A typical thickness for a layer of p-doped nanoparticles is about 40 nm and about 400 nm, if the p-i-n junction is to be incorporated into an optoelectronic device, such as a photovoltaic cell. However, nanoparticle layers having thicknesses outside of this range may also be used. After the layer of p-doped semiconductor nanoparticles is deposited, the nanoparticles may be subjected to flash lamp processing as illustrated in FIG. 1 resulting in the formation of a sintered, densified, p-doped semiconductor thin film 180′, as shown in FIG. 2F. Typical thicknesses for such a thin film may be about 20 nm to about 200 nm, although thin films having thicknesses outside this range may also be formed.

Finally, though not shown in the sequence of FIGS. 2A-2F, after processing to form the p-i-n junction is complete, a transparent conductive oxide (TCO) may be deposited on the p-type thin film layer 180. This not only provides a second electrode, but also allows a photon flux to penetrate to the photoconductive layers of the p-i-n junction. Materials useful for the TCO layer include, but are not limited to, indium tin oxide (ITO), tin oxide (TO), and zinc oxide (ZnO). Other materials contemplated for use in the TCO layer include, but are not limited to, conductive polymers from the family of 3,4 ethylenedioxythiophene conducting polymers, polyanilines, and conducting materials such as fullerenes. Such materials may be prepared as liquid suspensions, and as such may be readily applied and cured. For various embodiments of photoconductive devices, the TCO layer thickness may be from about 100 nm to about 200 nm.

Referring now to FIGS. 3A-B, an alternative process is shown for fabricating a p-i-n junction from Group IV semiconductor nanoparticles using flash lamp processing, in accordance with the invention. In both FIGS. 2A-F and in FIGS. 3A-B, like numbers denote like layers in the structure. In addition, the materials and dimensions of the various layers in FIGS. 3A-B may be same as those of the corresponding layers in FIGS. 2A-F. However, in contrast to the processing sequence depicted in FIGS. 2A-F, the processing sequence shown in FIGS. 3A-B begin with the serial deposition of a layer of n-doped semiconductor nanoparticles 140, followed by the deposition of a layer of intrinsic semiconductor nanoparticles 160, followed by the deposition of a layer of p-doped semiconductor nanoparticles 180, as shown in FIG. 3A. Once this multilayered stack of semiconductor nanoparticles is formed, it may be subjected to a single flash lamp processing step (of the type illustrated in FIG. 1) to form a multilayered thin film stack comprising an n-doped semiconductor thin film 140′, an intrinsic semiconductor thin film 160′, and a p-doped semiconductor thin film 180′, as shown in FIG. 3B.

By using the appropriate energy density and duration, and suitable nanoparticle layer thicknesses, a uniform, or substantially uniform, density may be achieved across the thickness of a single semiconductor thin film, in the case of a single layer structure, or across multiple semiconductor thin films, in the case of a multilayered structure. Alternatively, a structure having a heterogeneous density profile may be formed.

For example, in the case of a single layer structure, the thin film may have a density gradient over its thickness, with a higher density at the top surface of the film and a lower density at the bottom layer, due to the higher processing temperatures toward the top surface of the layer. Alternatively, in a multilayered structure containing differently-doped semiconductor layers, the doped layers (or more highly doped layers) generally will tend to absorb more of the electromagnetic radiation during processing, resulting in the formation of a denser thin film.

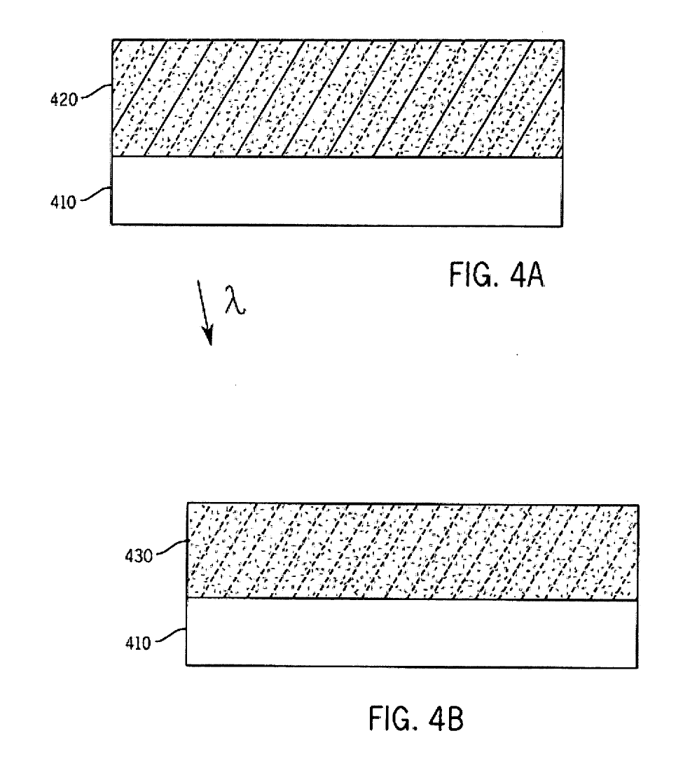

Referring now to FIG. 4, a typical device architecture used with native Group IV semiconductor substrate is shown. A layer of undoped or n-type or p-type doped nanoparticles 420 may be first deposited on the substrate 410 as shown in FIG. 4A and exposed to the flash lamp process forming a densified film 430 as shown in FIG. 4B. For this configuration, an insulating barrier or conductive electrode are not required as the substrate is conductive and typically is not a significant source of contamination. The native Group IV semiconductor substrates contemplated for use with Group IV semiconductor nanoparticles include, but are not limited to, crystalline silicon wafers of a variety of orientations. For example, the substrate may be a wafer of silicon (100), a wafer of silicon (111), or a wafer of silicon (110). Such crystalline substrate wafers may be doped with p-type dopants, such as boron, gallium, and aluminum. Alternatively, the silicon wafers may be doped with n-type dopants, such as arsenic, phosphorous, and antimony. Other native silicon substrates include doped and undoped polycrystalline silicon.

As the flash lamp process is designed to minimize dopant diffusion, this approach may be especially useful for generating abrupt dopant profiles in Group IV semiconductor devices. In the microelectronics industry, dopants are typically incorporated by one of two methods, ion implantation followed by thermal dopant activation or by diffusion from a gas or solid source. Both of these approaches result in diffuse dopant profiles which may be detrimental for device performance.

### EXAMPLES

### Example 1

### Single Layer Film Formation from Nanoparticles

Undoped Silicon nanoparticles particles were prepared in an RF reactor similar to that described as described in detail in U.S. patent application Ser. No. 11/842,466 entitled In Situ Doping of Group IV Semiconductor Nanoparticles and Thin Films Formed Therefrom, the entire disclosure of which is incorporated by reference.

Group IV semiconductor thin films were formed from silicon nanoparticles. The substrate used for silicon thin films was a 1″×1″×0.04″ quartz substrate previously coated with 100 nm thick molybdenum layer. The substrate was cleaned using an argon plasma. The silicon nanoparticle inks used in the formation of the thin films were prepared in an inert environment. Silicon nanoparticle ink was formulated as a 20 mg/ml solution in chloroform/chlorobenzene (4:1 v/v), which was sonicated using a sonication horn at 35% power for 15 minutes. Enough ink to effectively cover the substrate was delivered to the substrate surface, and silicon nanoparticle porous compacts were formed by spin casting the inks on the substrate at 1000 rpm for 60 seconds. After the formation of the silicon nanoparticle porous compacts, which were between about 650 nm to about 700 nm thick silicon thin films were fabricated using a solvent removal step of baking the porous compact at 100° C. for 30 minutes in an inert ambient.

After the solvent removal step, the substrate was transferred into the flash lamp chamber which was operated at atmospheric pressure. Similar results were obtained when the flash lamp chamber was operated under reduced pressure. Once the samples were loaded into the chamber, the chamber ambient was purged with 18 SLM argon for 1 minute. At that point, the halogen lamps were turned on and the temperature of the substrate was increased to 500° C. in one minute. After a 1 minute hold at 500° C., the flash lamps were turned on, irradiating the sample with the energy of 15 J/cm² in 0.8 milliseconds. As described above to obtain similar results using a longer pulse of 3 milliseconds requires a higher flash energy of ˜22 J/cm².

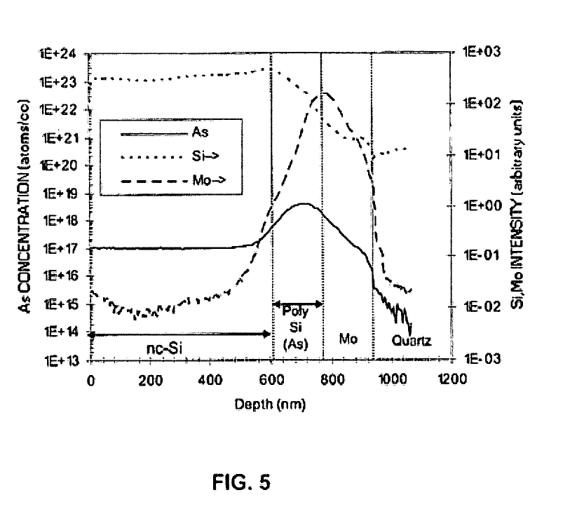

Referring now to FIGS. 5A-B, a set of scanning electron micrographs is shown of a single Si nanoparticle film before and after flash-lamp processing, in accordance with the invention. FIG. 5A shows the SEM micrograph of the unsintered film deposited on a molybdenum coated quartz substrate. The nanoparticle film is approximately 650 nm thick and is composed of an assembly of individually resolvable nanoparticles each smaller than 10-15 nm. The 100 nm thick molybdenum film under the silicon layer has a columnar microstructure with a lateral grain size of 20-30 nm.

The microstructure of the film after flash lamp processing is shown in FIG. 5B. As a result of the densification that took place during flash lamp treatment, the film thickness has decreased by approximately 50%. Also, the individual nanoparticles are no longer resolvable. Instead the film is composed of large fully densified grains approximately 500 nm in lateral dimension. Transmission electron microscopy of this film confirms the single-crystalline nature of each large grain.

### Example 2

### Multi-Layer Film Formation from Nanoparticles

Silicon nanoparticles of about 8 nm diameter were formed as described in Example 1. The Group IV semiconductor nanoparticle ink was prepared as a 20 mg/ml formulation of t-butoxy capped particles in DEGDE as described in detail in U.S. patent application Ser. No. 60/915,817 entitled Preparation Of Group IV Semiconductor Nanoparticle Materials And Dispersions Thereof, the entire disclosure of which is incorporated by reference.

A layer of silicon nanoparticles of about 450 nm in thickness was deposited in an inert nitrogen atmosphere using inkjet printing on top of a quartz substrate that has previously been coated with a 100 nm layer of molybdenum followed by a 50 nm thick layer of arsenic-doped polysilicon. This printed porous compact layer was heated at 200° C. in nitrogen atmosphere for 30 minutes. Under these conditions, excess solvent was driven off, and the film was more mechanically stable. Similarly to what is described in Example 1, the sample was processed in the flash lamp system, with the only difference that the flash energy was 12 J/cm².

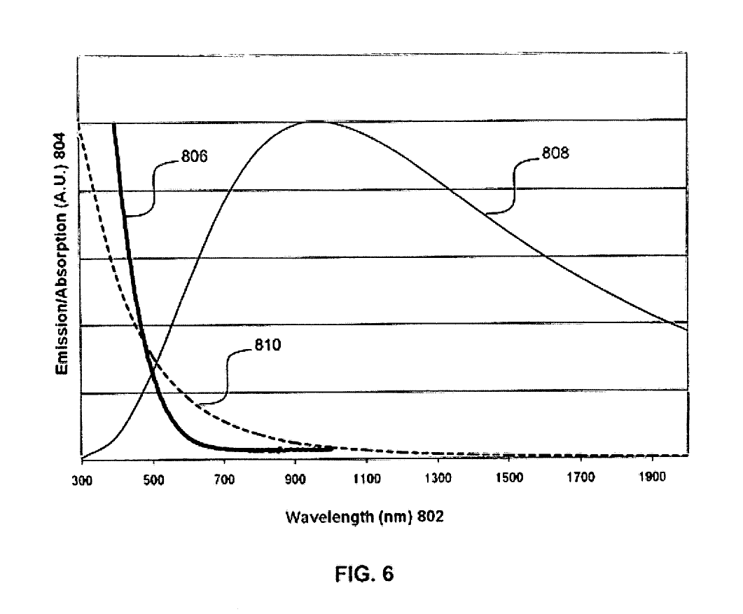

Referring now to FIG. 6, a scanning electron micrograph is shown of an Si nanoparticle film deposited on a dense Si layer and processed with a flash lamp, in accordance with the invention. As compared to the film described in Example 1, as a result of a slightly lower flash energy, the nanoparticle film is not fully dense. The nanoparticle based film is composed of large dense chunks or grains ranging in size from about 60 nm to about 200 nm, with the majority of the larger intermediate size grains positioned closer to the surface of the film. The bottom of the nanoparticle based film is fused to the polysilicon layer which lies on top of the molybdenum film.

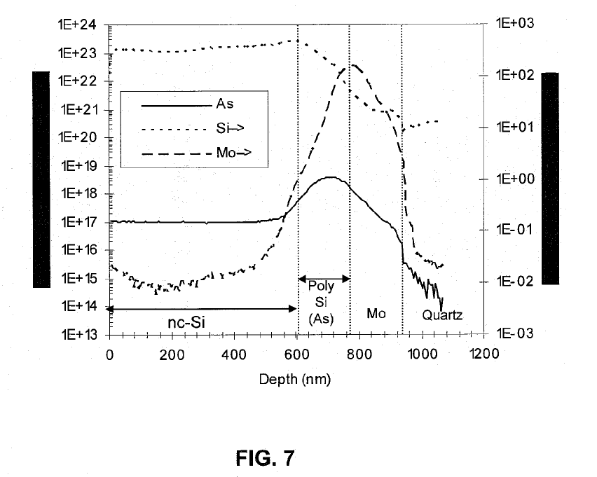

Referring now to FIG. 7, a SIMS analysis is shown of an intrinsic Si nanoparticle film deposited on an arsenic doped poly-silicon layer and processed with a flash lamp, in accordance with the invention. The arsenic content in the bulk of the nc-Si film is constant through the thickness of the film and is two orders of magnitude lower than the arsenic content in the doped poly-silicon layer, indicating that there is insignificant diffusion of arsenic into the nc-Si film as a result of the flash-lamp treatment, demonstrating formation of an intrinsic layer on top of an n-type layer. Similarly, molybdenum does not show significant diffusion through the silicon layer, even though silicon reacts with molybdenum for temperatures exceeding 800-1000° C., indicating that the bottom of the film stack did not reach temperatures of that magnitude.

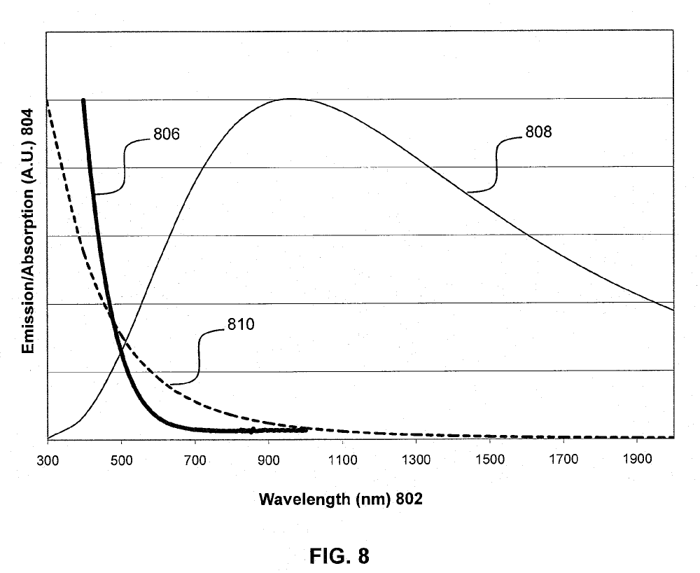

Referring now to FIG. 8, a simplified comparison is shown of a halogen lamp emission and a flash lamp emission to the absorption spectrum of a typical Si nanoparticle film, in accordance with the invention. Wavelength in nm is shown on horizontal axis 802, while emission/absorption in A.U. (arbitrary units). is shown on vertical axis 804. Plot 806 shows particle absorption profile for a Si nanoparticle film. Plot 808 shows the emission profile of a halogen lamp (with a color temperature of about 3000K), while plot 810 shows the emission profile of a flash lamp (with a color temperature of about 15000K).

As previously described, a thin film substantially containing nanoparticles below about 8 nm is diameter can directly absorb radiation with a wavelength shorter than approximately ˜750 nm. Above this wavelength, the heating is indirect, first being absorbed by the underlying substrate, and then being transferred into the thin film.

The emission profile of a flash lamp, as shown in plot 810, closely matches the absorption profile of the thin film, shown in plot 806. Consequently, in a thermally efficient manner, the use of a flash lamp allows the nanoparticles in the radiated layer to be directly converted into dense, sintered, semiconductor thin film. The individual layers of semiconductor may thus be selectively thermally processed in a multilayer structure, without heating adjacent, underlying layers, minimizing or eliminating unwanted dopant atom diffusion between layers and/or to utilize substrate materials having low melting temperature.

In contrast, the emission profile of a halogen lamp 808 is follows a more normal distribution that is substantially offset from the emission/absorption nanoparticle profile 806. Consequently, multiple radiation pulses may be required to first heat the substrate in order to indirectly conduct energy into the Si particle thin film.

For the purposes of this disclosure and unless otherwise specified, “a” or “an” means “one or more.” All patents, applications, references and publications cited herein are incorporated by reference in their entirety to the same extent as if they were individually incorporated by reference.

The invention has been described with reference to various specific and illustrative embodiments. However, it should be understood that many variations and modifications may be made while remaining within the spirit and scope of the invention.

Having disclosed exemplary embodiments and the best mode, modifications and variations may be made to the disclosed embodiments while remaining within the subject and spirit of the invention as defined by the following claims.

What is claimed is:

1. A method for creating a Group IV semiconductor densified thin film, comprising:
applying a colloidal dispersion to a substrate, wherein the colloidal dispersion includes a plurality of Group IV semiconductor nanoparticles and an organic solvent;
removing the organic solvent by applying a first temperature for a first time period to form a Group IV semiconductor non-densified thin film;
heating the Group IV semiconductor non-densified thin film to a second temperature for a second time period, wherein the second temperature is a pre-heating target temperature;
heating the Group IV semiconductor non-densified thin film to a third temperature for a third time period with a flash lamp apparatus, wherein the third temperature is equal to or greater than a sintering temperature;
wherein a Group IV semiconductor densified thin film is created.

2. The method of claim 1, wherein the plurality of Group IV semiconductor nanoparticles includes at least one of p-doped nanoparticles, n-doped nanoparticles, and intrinsic nanoparticles.

3. The method of claim 1, wherein the Group IV semiconductor densified thin film has a thickness of no greater than about 500 nm.

4. The method of claim 1, wherein the first temperature is between about 100° C. and about 450° C.

5. The method of claim 3, wherein the first time period is between about 5 minutes and about 30 minutes.

6. The method of claim 1, wherein the second temperature is between about 100° C. and about 800° C.

7. The method of claim 5, wherein the second time period is between about 0.5 minutes and about 5 minutes.

8. The method of claim 6, wherein the second temperature is applied using at least one of a heat lamp, RTP, and a hot plate.

9. The method of claim 1, wherein the flash lamp apparatus is configured to emit radiation from about 400 nm to about 750 nm.

10. The method of claim 8, wherein the flash lamp apparatus has a flash energy density of between about 3 J/cm² to about 120 J/cm².

11. The method of claim 9, wherein the third time period is between about 0.8 msec and about 3 msec.

12. A method for creating a set of Group IV semiconductor densified thin films, comprising:
applying a first colloidal dispersion to a substrate, wherein the first colloidal dispersion includes a first plurality of Group IV semiconductor nanoparticles and a first organic solvent;
applying a second colloidal dispersion to the first colloidal dispersion, wherein the second colloidal dispersion includes a second plurality of Group IV semiconductor nanoparticles and a second organic solvent;
removing the first organic solvent and the second organic solvent by applying a first temperature for a first time period to form a first Group IV semiconductor non-densified thin film and a second Group IV semiconductor non-densified thin film;
heating the first Group IV semiconductor non-densified thin film and the second Group IV semiconductor non-densified thin film to a second temperature for a second time period, wherein the second temperature is a pre-heat temperature;
heating the first Group IV semiconductor non-densified thin film and the second Group IV semiconductor non-densified thin film to a third temperature for a third time period with a flash lamp apparatus, wherein the third temperature is equal to or greater than a sintering temperature;
wherein a third Group IV semiconductor densified thin film and a fourth Group IV semiconductor densified thin film are created.

13. The method of claim 11, wherein the first Group IV semiconductor densified thin film and the second Group IV semiconductor densified thin film has a thickness of no greater than about 500 nm.

14. The method of claim 11, wherein the first temperature is between about 100° C. and about 450° C.

15. The method of claim 13, wherein the first time period is between about 5 minutes and about 30 minutes.

16. The method of claim 11, wherein the second temperature is between about 100° C. and about 800° C.

17. The method of claim 15, wherein the second time period is between about 0.5 minutes and about 5 minutes.

18. The method of claim 16, wherein the second temperature is applied using at least one of a heat lamp, RTP, and a hot plate.

19. The method of claim 11, wherein the flash lamp apparatus is configured to emit radiation from about 400 nm to about 750 nm.

20. The method of claim 18, wherein the flash lamp apparatus has a flash energy density of between about 3 J/cm² to about 120 J/cm².

21. The method of claim 18, wherein the third time period is between about 0.8 msec and about 3 msec.

22. The method of claim 12, wherein the first plurality of Group IV semiconductor nanoparticles include N-type dopants, and the second plurality of Group IV semiconductor nanoparticles include P-type dopants.

23. The method of claim 12, wherein the first plurality of Group IV semiconductor nanoparticles include P-type dopants, and the second plurality of Group IV semiconductor nanoparticles include N-type dopants.
